(19) United States
(12) Patent Application Publication
(10) Pub. No.: US 2026/0351468 A1
(43) Pub. Date: Nov. 5, 2026

(54) COIL ASSEMBLY

(71) Applicant: Robert Bosch GmbH, Stuttgart (DE)

(72) Inventors: Gellert Tanczos, Kecskemét (HU); Heiner Jacobs, Baden-Baden (DE); Jan Walker, Karlsruhe (DE); Moritz Meyer, Engstingen (DE)

(21) Appl. No.: 19/118,540

(22) PCT Filed: Apr. 2, 2024
(86) PCT No.: PCT/EP2024/058952

§ 371 Date: Apr. 4, 2025

(30) Foreign Application Priority Data
Apr. 6, 2023 (DE) 10 2023 203 239.2

(51) Int. Cl. H01F 27/30; H01F 27/24; H01F 27/28

(52) U.S. Cl. CPC H01F 27/306; H01F 27/24; H01F 27/2876

(57) ABSTRACT

A coil assembly. The coil assembly includes a circuit carrier, an electrical coil, the winding of which is wound around a magnetic core and engages through an inner opening, and a cooling arrangement, wherein at least two turns each have an electrically conductive conductor piece with two end pieces which are each inserted and brought into contact in an electrical via. On a surface of the circuit carrier facing the coil in the region of the magnetic core, the cooling arrangement has a plurality of first conductor structures which are thermally coupled using at least one thermal via to a plurality of associated second conductor structures on a surface of the circuit carrier facing away from the coil. The first conductor structures are disposed spaced apart from one another and are each connected to at least one of the electrical vias.

### FIELD

The present invention relates to a coil assembly including a circuit carrier and at least one electrical coil, the winding of which is wound with at least two turns around a magnetic core enclosing at least one inner opening and engages through the at least one inner opening.

### BACKGROUND INFORMATION

An inductive component is described in German Patent Application No. DE 10 2016 210 746 A1, that includes a ring core made of soft magnetic material which annularly surrounds an inner opening and at least two electrically conductive conductor pieces that less than completely surround the ring core through the inner opening and each comprise two conductor end sections. The conductor end sections are led away from the ring core parallel to one another and perpendicular to the ring core and are electrically connected to one another to form at least one winding. The conductor end sections are disposed outside the inner opening and outside an imagined extension of the inner opening in axial direction. The inductive component is disposed on an electrically insulating carrier plate with bores, which comprises electrically conductive structures at least in the vicinity of the bores. The conductor end sections of the conductor pieces are led through the bores and electrically connected to one another via the electrically conductive structures to form at least one winding.

### SUMMARY

A coil assembly with certain features of the present invention may have the advantage that the cooling of the at least one electrical coil takes place via the circuit carrier. According to an example embodiment of the present invention, to do this, cooling paths can be provided for each of the individual turns of the at least one electrical coil by thermal connections through the circuit carrier to at least one cooling element disposed on the surface of the circuit carrier facing away from the coil. The at least one cooling element can be disposed on the surface of the circuit carrier facing away from the coil, preferably within a region covered by the at least one electrical coil. At least one cooling element can additionally or alternatively be disposed on the surface of the circuit carrier facing away from the coil outside the region covered by the at least one electrical coil. Example embodiments of the present invention also enable additional cooling of the at least one coil on a side of the at least one coil facing away from the circuit carrier, on which a further cooling element can be mounted on the winding of the at least one coil.

The electrical contact between the individual turns of the at least one coil on the circuit carrier advantageously enables improved heat dissipation over the individual cooling paths so that a higher power loss of the at least one coil can be made possible. This enables a higher power density or packing density and consequently makes it possible to achieve a reduced installation space requirement. It is moreover also possible to achieve a scalability of the design of the at least one coil and the thermal conductor structures of the circuit carrier, and thus the cooling paths for each individual turn, with the same space requirement.

Example embodiments of the present invention provide a coil assembly comprising a circuit carrier, at least one electrical coil, the winding of which is wound with at least two turns around a magnetic core enclosing at least one inner opening and engages through the at least one inner opening, and at least one cooling arrangement. The at least two turns each comprise an electrically conductive conductor piece with two end pieces which are each inserted and brought into contact in an electrical via incorporated in the circuit carrier. On a surface of the circuit carrier facing the coil in the region of the magnetic core, the cooling arrangement here has at least two first thermal conductor structures which are thermally coupled by means of at least one thermal via to at least two associated second thermal conductor structures on a surface of the circuit carrier facing away from the coil. The at least two first thermal conductor structures are disposed spaced apart from one another and are each connected to at least one of the electrical vias, and the at least two second thermal conductor structures are disposed spaced apart from one another and are thermally coupled to at least one cooling element disposed on the surface of the circuit carrier facing away from the coil, so that a respective cooling path is formed between the end pieces of the at least two turns that are in contact with corresponding electrical vias and the at least one cooling element.

In the present case, a magnetic core can be understood to be a circular or oval or rectangular ring core with or without a central web, which is preferably made of a soft magnetic material.

Example embodiments of the coil assembly according to the present invention can be used as choke coils for suppressing interference in electrical and electronic circuits in high-voltage or high-current applications, for instance. Such interference suppression choke coils can preferably be used to suppress interference currents that occur in the same direction in forward and return lines. Such current-compensated choke coils can also be referred to as common mode choke coils and comprise a number of identical windings through which the working current flows in opposite directions. In ideal, completely symmetrical windings comprising the same number of turns and the same wire routing, the magnetic fields of the individual windings in the magnetic core of the choke coils therefore cancel each other out, so that the choke coil has a low inductance for the working current, while the inductance of the choke coil for the interference currents that occur in the same direction is significantly higher.

In the present case, an electrical via can be understood to be a through opening in the circuit carrier that comprises an electrically conductive wall or sleeve. The individual end pieces of the turns can be inserted into such an electrical via and soldered to the wall or sleeve of the via and thermal conductor structures of the circuit carrier in a subsequent soldering process. The cross-section of the electrically conductive wall or sleeve and the cross-section of the end pieces of the individual turns can preferably be selected such that a circumferential gap is created between the inserted end piece and the electrically conductive wall or sleeve of the electrical via, which facilitates the insertion of the end piece and allows the solder to pass through during soldering. The thermal conductor structure also has a certain minimum width in the region of the electrical via. The thermal conductor structures on the surface facing the coil and on the surface of the circuit carrier facing away from the coil can each be made of a material with good thermal and electrical conductivity, such as copper.

Advantageous improvements of the coil assembly of the present invention are made possible by the measures and further developments disclosed herein.

According to an example embodiment of the present invention, it is particularly advantageous that the circuit carrier can be embodied as a multilayer printed circuit board comprising at least one electrically and thermally conductive inner layer, which is connected to the at least one thermal via and the at least one electrical via. The number and thickness of the individual thermally and electrically conductive inner layers, which are preferably made of copper, and the corresponding insulation layers can be selected and specified taking into account the legal standards in such a way that the cooling paths of the individual turns of the at least one coil are activated and optimized.

In an advantageous configuration of the coil assembly of the present invention, the electrically conductive conductor piece of the at least two turns can each be U-shaped. In this case, one of the two end pieces of the at least two turns can be embodied as a straight electrically conductive conductor piece and the other of the two end pieces can be embodied as an S-shaped electrically conductive conductor piece, wherein sections of the two end pieces of the at least two turns inserted into the electrical vias extend parallel to one another in axial direction outside the at least one inner opening and outside an imagined extension of the at least one inner opening. This makes it possible to achieve a particularly compact design of the coil assembly.

In another advantageous configuration of the coil assembly of the present invention, at least one of the at least two first thermal conductor structures on the surface of the circuit carrier facing the coil can electrically connect two electrical vias, into each of which an end piece of two adjacent turns of the winding of the at least one coil is inserted, to one another in such a way that the two adjacent turns of the winding of the at least one electrical coil are electrically connected in series. A first end piece can form an input contact of a corresponding turn, for example. A second end piece can form an output contact of the corresponding turn. This means that a second end piece, which forms the output contact of a first turn and is inserted and brought into electrical contact in a first via, is thermally and electrically connected via the corresponding first thermal conductor structure to a second via, into which a first end piece which forms the input contact of a second turn is inserted and brought into electrical contact. In this case, the second end piece of the first turn and the first end piece of the second turn can each be soldered to the corresponding via.

Alternatively, according to an example embodiment of the present invention, at least one of the at least two first thermal conductor structures on the surface of the circuit carrier facing the coil can comprise an electrical via embodied as an elongated hole into which two end pieces of two adjacent turns of the winding of the at least one coil can be inserted and electrically connected to one another in such a way that the two adjacent turns of the winding of the at least one coil are electrically connected in series. This means that the second end piece, which forms the output contact of the first turn, and the first end piece, which forms the input contact of the second turn, can be inserted and brought into electrical contact in the same via. In this case, the second end piece of the first turn and the first end piece of the second turn can be soldered to the same via. Such an electrical via embodied as an elongated hole allows the two end pieces of the two adjacent turns to be easily electrically and thermally connected to one another. The smaller distance between the two end pieces also makes it possible to reduce the overall diameter of the coil assembly. This increases the electrical connectivity due to the direct contact of a solder of a material-locking connection with the two end pieces and the wall of the via embodied as an elongated hole.

In another advantageous example configuration of the coil assembly of the present invention, the at least one of the at least two first thermal conductor structures can comprise a connection for an electrical component. A smoothing capacitor or an ohmic resistor or a contact connection, for instance, can easily be disposed between two turns of the at least one coil.

In another advantageous configuration of the coil assembly of the present invention, a first end piece of a first turn of the winding can form a first contact or input contact and a second end piece of a last turn of the winding can form a second contact or output contact of the at least one coil and they can each be inserted and brought into contact in an electrical via embodied as a bore hole.

In another advantageous configuration of the coil assembly of the present invention, the at least two first thermal conductor structures can be formed on free surfaces of the surface of the circuit carrier facing the coil in the direction of the at least one inner opening under the magnetic core and/or in the direction away from the magnetic core outside the magnetic core. In particular in the configuration in the direction of the magnetic core, unused surfaces under the magnetic core can be used for the first thermal conductor structures to save installation space. Depending on the size of the circuit carrier, however, the first thermal conductor structures can also be configured outside in the vicinity of the magnetic core.

In another advantageous configuration of the coil assembly of the present invention, the shape and dimensions of the at least two first thermal conductor structures on the surface of the circuit carrier facing the coil and the at least two second thermal conductor structures on the surface of the circuit carrier facing away from the coil and the at least one inner layer of the circuit carrier and a number of thermal vias can be adapted to the thermal load conditions. This advantageously makes it easy to optimally adapt the individual cooling paths for cooling the individual turns of the at least one coil to the thermal conditions of the coil assembly.

In another advantageous configuration of the coil assembly of the present invention, at least one electrically insulating and thermally conductive layer can be inserted between the at least one cooling element and the at least two second thermal conductor structures on the surface of the circuit carrier facing away from the coil. An area of the electrically insulating and thermally conductive layer can then be larger than an area of the at least two second thermal conductor structures, which can be larger than an area of the at least one cooling element. To compensate unevenesses and to improve the thermal transition, a layer with good thermal conductivity can be inserted between the electrically insulating and thermally conductive layer and the at least one cooling element.

In another advantageous configuration of the coil assembly of the present invention, in order to avoid creepage distances between the at least one electrical via and the at least one cooling element disposed on the surface of the circuit carrier facing away from the coil, an edge of the at least one cooling element can have a first minimum distance and an edge of the at least one thermal via can have a second minimum distance which is less than the first minimum distance, and an edge of the at least two second thermal conductor structures can have a third minimum distance which is less than the second minimum distance, and an edge of the electrically insulating and thermally conductive layer can have a fourth minimum distance from the at least one electrical via which is less than the third minimum distance. These minimum distances are selected and specified here taking into account the legal standards.

In another advantageous configuration of the coil assembly of the present invention, the cooling arrangement can comprise at least one further cooling element which can be positioned on the winding of the at least one coil on a side of the at least one coil facing away from the circuit carrier. The at least one further cooling element can then be thermally coupled to the winding of the at least one coil via at least one electrically insulating and thermally conductive structure. In addition to the “downward” cooling of the individual turns of the at least one electrical coil of the coil assembly by the circuit carrier, the at least one further cooling element advantageously enables “upward” cooling of the at least one coil of the coil assembly. Embodiment examples of the present invention are shown in the figures and explained in more detail in the following description. In the figures, the same reference signs designate components or elements that perform the same or analogous functions.

### BRIEF DESCRIPTION OF THE DRAWINGS

FIG. 1 shows a schematic perspective view of a first embodiment example of a coil assembly according to the present invention.

FIG. 2 shows a schematic plan view onto the coil assembly according to the present invention of FIG. 1 without a magnetic core.

FIG. 3 shows a schematic perspective view of two adjacent turns of the coil assembly according to the present invention of FIGS. 1 and 2.

FIG. 4 shows a schematic plan view onto a section of a circuit carrier of the coil assembly according to the present invention of FIGS. 1 and 2.

FIG. 5 shows a schematic sectional view through a section of the circuit carrier of the coil assembly according to the present invention of FIGS. 1 and 2.

FIG. 6 shows a schematic plan view onto the circuit carrier of the coil assembly according to the present invention of FIGS. 1 and 2 without electrical coils.

FIG. 7 shows a schematic illustration of the circuit carrier of the coil assembly according to the present invention of FIGS. 1 and 2 from below without cooling elements and without an electrically insulating and thermally conductive layer.

FIG. 8 shows a schematic illustration of the circuit carrier of the coil assembly according to the present invention of FIGS. 1 and 2 from below.

FIG. 9 shows a schematic perspective partial sectional view of a second embodiment example of a coil assembly according to the present invention without a magnetic core.

### DETAILED DESCRIPTION OF EXAMPLE EMBODIMENTS

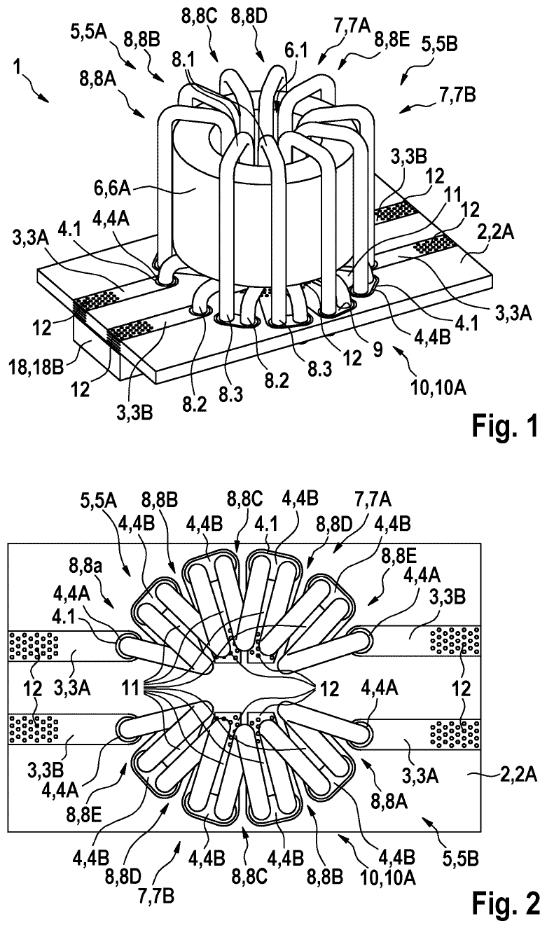

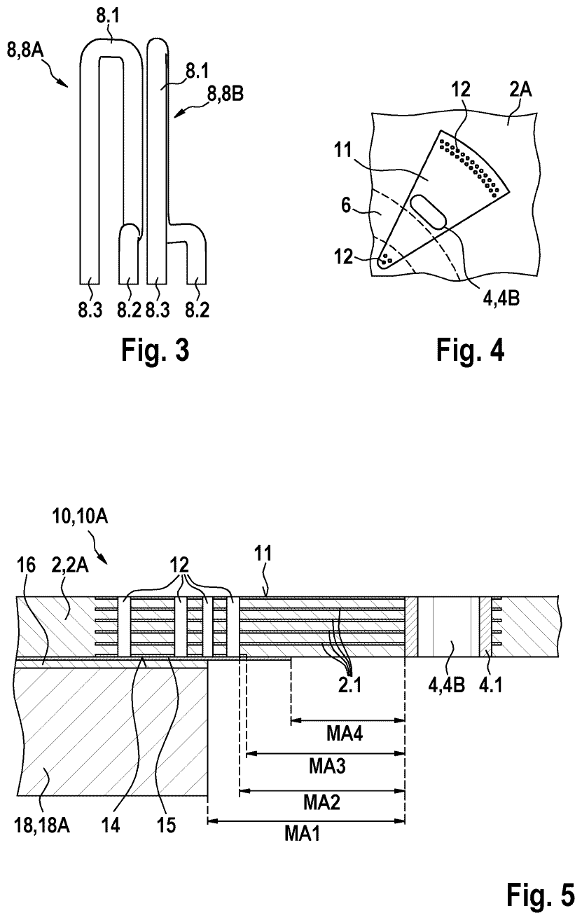

As can be seen from FIG. 1 to 9, the shown embodiment examples of a coil assembly 1, 1A, 1B according to the present invention each include a circuit carrier 2, at least one electrical coil 5, the winding 7 of which is wound with at least two turns 8 around a magnetic core 6 enclosing at least one inner opening 6.1 and engages through the at least one inner opening 6.1, and at least one cooling arrangement 10, 10A, 10B. The at least two turns 8 each comprise an electrically conductive conductor piece 8.1 with two end pieces 8.2, 8.3 which are each inserted and brought into contact in an electrical via 4 incorporated in the circuit carrier 2. On a surface of the circuit carrier 2 facing the coil in the region of the magnetic core 6, the cooling arrangement 10, 10A, 10B here has at least two first thermal conductor structures 3, 11 which are thermally coupled by means of at least one thermal via 12 to at least two associated second thermal conductor structures 13, 14 on a surface of the circuit carrier 2 facing away from the coil. The at least two first thermal conductor structures 3, 11 are disposed spaced apart from one another and are each connected to at least one of the electrical vias 4, and the at east two second thermal conductor structures 13, 14 are disposed spaced apart from one another and are thermally coupled to at least one cooling element 18 disposed on the surface of the circuit carrier 2 facing away from the coil, so that a respective cooling path is formed between the end pieces 8.2, 8.3 of the at least two turns 8 that are in contact with corresponding electrical vias 4 and the at least one cooling element 18.

As can further be seen from FIG. 1, the coil assembly 1 is embodied as a common mode choke for high-voltage or high-current applications. For this purpose, the magnetic core 6 in the shown embodiment example is embodied as a circular ring core 6A with an inner opening 6.1 and is aligned parallel to the surface of the circuit carrier 2. In the shown embodiment example, the windings 7 of two electrical coils 5 are wound on this ring core 6A. A first coil 5A comprises a first winding 7A with five turns 8A, 8B, 8C, 8D, 8E. A second coil 5B is symmetrical to the first coil 5A and comprises a second winding 7B which likewise has five turns 8A, 8B, 8C, 8D, 8E. The same principle can be applied with only one coil or with more than two coils.

In alternative, not depicted, embodiment examples of the coil assembly 1, the magnetic core 6 is embodied as an oval or rectangular ring core 6A with an inner opening 6.1. In other not depicted alternative embodiment examples, the ring core 6A has a central web so that the corresponding magnetic core 6 has two inner openings irrespective of its shape.

As can be seen in particular in FIG. 5, the circuit carrier 2 in the shown embodiment examples is embodied as a multilayer printed circuit board 2A, for example with four electrically and thermally conductive inner layers 2.1 which are connected to the at least one thermal via 12 and the at least one electrical via 4.

As can further be seen from FIG. 1 to 3 and 9, each electrically conductive conductor piece 8.1 of the purely as an example embodied five turns 8A, 8B, 8C, 8D, 8E of the respective coil 5A, 5B is U-shaped. In each case, a first end piece 8.2 is embodied as an S-shaped electrically conductive conductor piece and forms an input contact of the respective turn 8A, 8B, 8C, 8D, 8E. A second end piece 8.3 is embodied as a straight electrically conductive conductor piece and forms an output contact of the respective turn 8A, 8B, 8C, 8D, 8E. Sections of the two end pieces 8.2, 8.3 of the respective turn 8A, 8B, 8C, 8D, 8E inserted into the electrical vias 4 extend parallel to one another in axial direction outside the at least one inner opening 6.1 and outside an imagined extension of the at least one inner opening 6.1. As can be seen in particular from FIG. 1, 2 and 6 to 8, the vias 4 in the shown embodiment example are disposed on a common circle around the magnetic core 6.

As can be seen in particular from FIGS. 1, 2 and 6, in the shown embodiment example, six first thermal conductor structures 3, 11 are disposed purely as an example on the surface of the circuit carrier 2 facing the coil for each coil 5A, 5B. Four first thermal conductor structures 11 each have the form of a piece of pie here and comprise an electrical via 4 embodied as an elongated hole 4B into which two respective end pieces 8.2, 8.3 of two adjacent turns 8A, 8B, 8C, 8D, 8E of the winding 7 of the respective coil 5 are inserted and electrically connected to one another in such a way that the two adjacent turns 8A, 8B, 8C, 8D, 8E of the winding 7 of the respective coil 5 are electrically connected in series. The pie-shaped first thermal conductor structures 11 are disposed on free surfaces of the surface of the circuit carrier 2 facing the coil in the direction of the at least one inner opening 6.1 under the magnetic core 6. Two of the first thermal conductor structures 3 each have a web shape and comprise a via 4 embodied as a bore 4A. The web-shaped first thermal conductor structures 3 are formed in the direction away from the magnetic core 6 outside the magnetic core 6.

FIG. 4 shows an alternative configuration of the pie-shaped first thermal conductor structures 11. The pie-shaped first thermal conductor structure 11 is formed here on free surfaces of the surface of the circuit carrier 2 facing the coil in the direction of the at least one inner opening 6. 1 under the magnetic core 6 shown with dased lines and outside the magnetic core 6.

As can further be seen from FIGS. 1 and 2, the first end piece 8.2 of a first turn 8A of the first winding 7A of the first coil 5A is inserted into the via 4 embodied as bore 4A of a web-shaped first thermal conductor structure 3A, at the top on the left-hand side in the illustration, and forms a first contact of the first coil 5A which corresponds here to the input contact of the first coil 5A. The second end piece 8.3 of the first turn 8A of the first coil 5A is inserted together with the first end piece 8.2 of a second turn 8B of the first coil 5A into an electrical via 4 embodied as an elongated hole 4B of a pie-shaped thermal conductor structure 11. The second end piece 8.3 of the second turn 8B of the first coil 5A is inserted together with the first end piece 8.2 of a third turn 8C of the first coil 5A into an electrical via 4 embodied as an elongated hole 4B of a pie-shaped thermal conductor structure 11. The second end piece 8.3 of the third turn 8C of the first coil 5A is inserted together with the first end piece 8.2 of a fourth turn 8D of the first coil 5A into an electrical via 4 embodied as an elongated hole 4B of a pie-shaped thermal conductor structure 11. The second end piece 8.3 of the fourth turn 8D of the first coil 5A is inserted together with the first end piece 8.2 of a fifth and last turn 8E of the first coil 5A into an electrical via 4 embodied as an elongated hole 4B of a pie-shaped thermal conductor structure 11. The second end piece 8.3 of the fifth and last turn 8E of the first coil 5A is inserted and brought into contact in an electrical via 4 embodied as a bore hole 4A of a web-shaped thermal conductor structure 3B, at the top right in the illustration, and forms a second contact of the first coil 5A which corresponds here to an output contact of the first coil 5A. The procedure is the same for embodiments with more or fewer turns.

As can further be seen from FIGS. 1 and 2, the first end piece 8.2 of a first turn 8A of the second winding 7B of the second coil 5B is inserted into the via 4 embodied as bore 4A of a web-shaped first thermal conductor structure 3A, the bottom on the right-hand side in the illustration, and forms a first contact of the second coil 5b which corresponds here to the input contact of the second coil 5B. The second end piece 8. 3 of the first turn 8A of the second coil 5B is inserted together with the first end piece 8.2 of a second turn 8B of the second coil 5B into an electrical via 4 embodied as an elongated hole 4B of a pie-shaped thermal conductor structure 11. The second end piece 8.3 of the second turn 8B of the second coil 5B is inserted together with the first end piece 8.2 of a third turn 8C of the second coil 5B into an electrical via 4 embodied as an elongated hole 4B of a pie-shaped thermal conductor structure 11. The second end piece 8.3 of the third turn 8C of the second coil 5B is inserted together with the first end piece 8.2 of a fourth turn 8D of the second coil 5B into an electrical via 4 embodied as an elongated hole 4B of a pie-shaped thermal conductor structure 11. The second end piece 8.3 of the fourth turn 8D of the second coil 5A is inserted together with the first end piece 8.2 of a fifth and last turn 8E of the second coil 5B into an electrical via 4 embodied as an elongated hole 4B of a pie-shaped thermal conductor structure 11. The second end piece 8.3 of the fifth and last turn 8E of the second coil 5B is inserted and brought into contact in an electrical via 4 embodied as a bore hole 4A of a web-shaped thermal conductor structure 3B, at the bottom left in the illustration, and forms a second contact of the second coil 5B which corresponds here to an output contact of the second coil 5B. An electrical load, such as an inverter for a three-phase motor, can be connected between the upper web-shaped thermal conductor structure 3B on the right in the illustration, which is connected to the output contact of the first coil 5A, and the lower web-shaped thermal conductor structure 3A on the right in the illustration, which is connected to the input contact of the second coil 5B. A DC voltage supply can be connected to each of the two web-shaped thermal conductor structures 3 on the left in the illustration. A positive DC voltage supply can be applied to the upper web-shaped thermal conductor structure 3A on the left in the illustration which is connected to the input contact of the first coil 5A, for instance. A negative DC voltage supply can be connected to the lower web-shaped thermal conductor structure 3B on the left in the illustration which is connected to the output contact of the second coil 5B, for instance. Embodiments with more or fewer turns are implemented in the same way.

In the shown embodiment examples, the electrical vias 4 comprise an electrically conductive wall 4.1 or sleeve, to which the inserted individual end pieces 8.2, 8.3 of the turns 8A, 8B, 8C, 8D, 8E of the two coils 5A, 5B are connected by a material-locking connection 9, preferably by a solder connection.

In an alternative, not depicted, embodiment example of the coil assembly 1, the four respective pie-shaped first thermal conductor structures 11 of the two coils 5A, 5B on the surface of the circuit carrier 2 facing the coil each have two electrical vias 4 embodied as bores 4A, into each of which an end piece 8.2, 8.3 of two adjacent turns 8A, 8B, 8C, 8D, 8E, 5A, 5B of the winding 7 are inserted. The pie-shaped first thermal conductor structures 11 here connect the two adjacent turns 8A, 8B, 8C, 8D, 8E of the respective coil 5A, 5B in such a way that they are electrically connected in series.

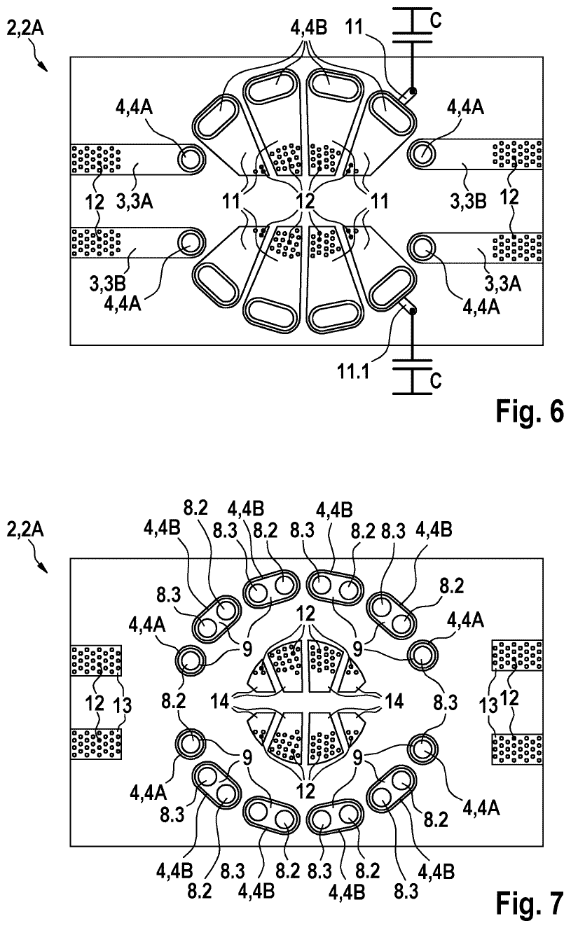

As can further be seen from FIG. 6, one of the pie-shaped first thermal conductor structures 11 of the two coils 5A, 5B comprises a respective connection 11.1 for an electrical component C. In the shown embodiment example, the two electrical components C each correspond to a smoothing capacitor.

As can further be seen from FIG. 7, in the shown embodiment example of the coil assembly 1A, six second thermal conductor structures 13, 14 are disposed-in each case purely as an example on the surface of the circuit carrier 2 facing away from the coil for each coil 5A, 5B. Four second thermal conductor structures 14 of the respective coil 5A, 5B here each have the form of a piece of pie and are thermally connected to the pie-shaped first thermal conductor structures 11 on the surface of the circuit carrier 2 facing the coil by means of a plurality of thermal vias 12. The pie-shaped second thermal conductor structures 12 are disposed on free surfaces of the surface of the circuit carrier 2 facing away from the coil in the direction of the at least one inner opening 6.1 under the magnetic core 6. Two of the second thermal conductor structures 13 of the respective coil 5A, 5B each have a web shape and are thermally connected to the web-shaped first thermal conductor structures 3 on the surface of the circuit carrier 2 facing the coil by means of a plurality of thermal vias 12. The web-shaped second thermal conductor structures 13 are formed in the direction away from the magnetic core 6 outside the magnetic core 6.

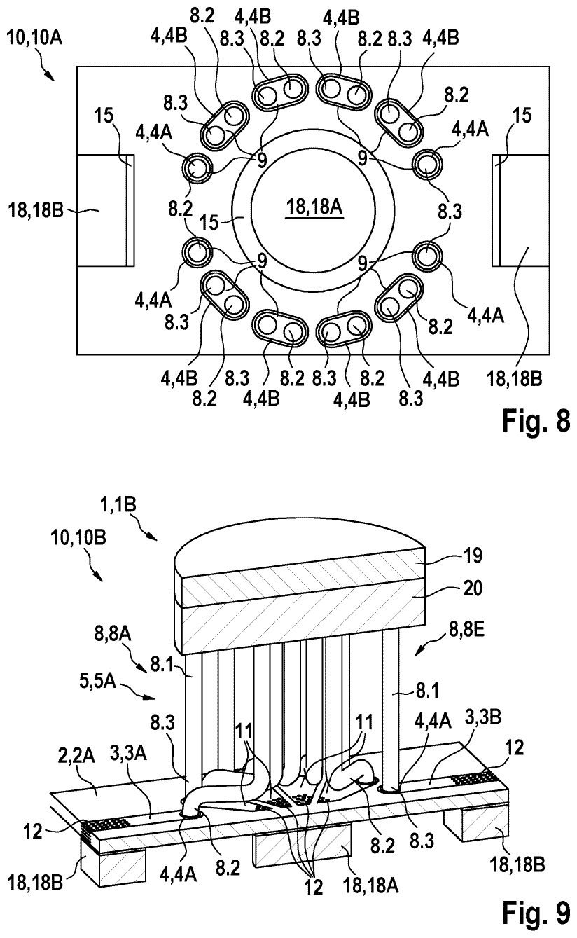

As can further be seen from FIGS. 5 and 8, at least one electrically insulating and thermally conductive layer 15 is inserted between the at least one cooling element 18 and the at least two second thermal conductor structures 13, 14 on the surface of the circuit carrier 2 facing away from the coil. An area of the electrically insulating and thermally conductive layer 15 is then larger than an area of the at least two second thermal conductor structures 13, 14, which is larger than an area of the at least one cooling element 18. As can further be seen in particular from FIG. 8, a first cooling element 18 disposed under the magnetic core 6 in the shown embodiment example is embodied as a round cooling dome 18A. In the shown embodiment example, the further cooling elements 18 disposed outside the magnetic core 6 are each embodied as cuboid cooling blocks 18B.

As can further be seen from FIG. 5, an edge of the cooling element 18 embodied as a cooling dome 18A has a first minimum distance MA1 from the shown electrical via 4. An edge of the thermal via 12 disposed closest to the electrical via has a second minimum distance MA2 from the electrical via 4 which is less than the first minimum distance MA1. An edge of the second thermal conductor structures 14 has a third minimum distance MA3 from the electrical via 3 which is less than the second minimum distance MA2. An edge of the electrically insulating and thermally conductive layer 15 has a fourth minimum distance MA4 from the at least one electrical via 4 which is less than the third minimum distance MA3. The minimum distances MA1, MA2, MA3, MA4 are selected and specified here taking into account the legal standards in order to avoid creepage distances even in high-voltage or high-current applications. To compensate unevenesses and to improve the thermal transition, a layer 16 with good thermal conductivity can be inserted between the electrically insulating and thermally conductive layer 15 and the at least one cooling element 18 in the shown embodiment example.

The shape and dimensions of the first thermal conductor structures 3, 11 on the surface of the circuit carrier 2 facing the coil and the second thermal conductor structures 13, 14 on the surface of the circuit carrier 2 facing away from the coil and the inner layers 2.1 of the circuit carrier 2 and a number of thermal vias 12 is adapted to the thermal load conditions.

As can further be seen from FIG. 9, the second embodiment example of the coil assembly 1B shown corresponds substantially to the first embodiment example of the coil assembly 1A shown in FIG. 1 to 8, so that a repeated description of the same components is omitted. In contrast to the first embodiment example of the coil assembly 1A, a second embodiment example of the cooling arrangement 10B of the shown second embodiment example of the coil assembly 1B comprises at least one further cooling element 19, which is positioned on the winding 7 of the at least one coil 5 on a side of the at least one coil 5 facing away from the circuit carrier 2. To improve heat transfer, the shown further cooling element 19 is thermally coupled to the winding 7 of the at least one coil 5 via at least one electrically insulating and thermally conductive structure 20.

1-15. (canceled)

16. A coil assembly, comprising:
a circuit carrier;
at least one electrical coil, a winding of the coil being wound with at least two turns around a magnetic core enclosing at least one inner opening and engages through the at least one inner opening; and
and at least one cooling arrangement;
wherein the at least two turns each have an electrically conductive conductor piece with two end pieces which are each inserted and brought into contact in an electrical via incorporated in the circuit carrier;
wherein, on a surface of the circuit carrier facing the coil in a region of the magnetic core, the cooling arrangement has at least two first conductor structures which are thermally coupled by at least one thermal via to at least two associated second conductor structures on a surface of the circuit carrier facing away from the coil; and
wherein the at least two first conductor structures are disposed spaced apart from one another and are each connected to at least one of the electrical vias, and the at least two second conductor structures are disposed spaced apart from one another and are thermally coupled to at least one cooling element disposed on the surface of the circuit carrier facing away from the coil, so that a respective cooling path is formed between the end pieces of the at least two turns that are in contact with corresponding electrical vias and the at least one cooling element.

17. The coil assembly according to claim 16, wherein the circuit carrier is embodied as a multilayer printed circuit board including at least one electrically and thermally conductive inner layer which is connected to the at least one thermal via and the at least one electrical via.

18. The coil assembly according to claim 16, wherein each electrically conductive conductor piece of the at least two turns is U-shaped, wherein one of the two end pieces of the at least two turns is embodied as a straight electrically conductive conductor piece and the other of the two end pieces is embodied as an S-shaped electrically conductive conductor piece, wherein sections of the two end pieces of the at least two turns inserted into the electrical vias extend parallel to one another in axial direction outside the at least one inner opening and outside an imagined extension of the at least one inner opening.

19. The coil assembly according to claim 16, wherein at least one of the at least two first thermal conductor structures, on the surface of the circuit carrier facing the coil, electrically connects two electrical vias, into each of which an end piece of two adjacent turns of the winding of the at least one coil is inserted, to one another in such a way that the two adjacent turns of the winding of the at least one coil are electrically connected in series.

20. The coil assembly according to claim 16, wherein at least one of the at least two first thermal conductor structures on the surface of the circuit carrier facing the coil includes an electrical via embodied as an elongated hole into which two end pieces of two adjacent turns of the winding of the at least one coil are inserted and electrically connected to one another in such a way that the two adjacent turns of the winding of the at least one coil are electrically connected in series.

21. The coil assembly according to claim 19, wherein the at least one of the at least two first thermal conductor structures includes a connection for an electrical component.

22. The coil assembly according to claim 16, wherein an end piece of a first turn of the winding forms a first contact and an end piece of a last turn of the winding forms a second contact of the at least one coil and they are each inserted and brought into contact in an electrical via embodied as a bore hole.

23. The coil assembly according to claim 16, wherein the at least two first thermal conductor structures are formed on free surfaces of the surface of the circuit carrier facing the coil in a direction of the at least one inner opening under the magnetic core and/or in a direction away from the magnetic core outside the magnetic core.

24. The coil assembly according to claim 16, wherein the magnetic core is a circular or oval or rectangular ring core, with or without a central web.

25. The coil assembly according to claim 17, wherein a shape and dimensions of the at least two first thermal conductor structures on the surface of the circuit carrier facing the coil and the at least two second thermal conductor structures on the surface of the circuit carrier facing away from the coil and the at least one inner layer of the circuit carrier, and a number of thermal vias, are adapted to thermal load conditions.

26. The coil assembly according to claim 16, wherein at least one electrically insulating and thermally conductive layer is inserted between the at least one cooling element and the at least two second thermal conductor structures on the surface of the circuit carrier facing away from the coil.

27. The coil assembly according to claim 26, wherein an area of the electrically insulating and thermally conductive layer is larger than an area of the at least two second thermal conductor structures, which is larger than an area of the at least one cooling element.

28. The coil assembly according to claim 26, wherein an edge of the at least one cooling element has a first minimum distance and an edge of the at least one thermal via has a second minimum distance which is less than the first minimum distance, and an edge of the at least two second thermal conductor structures has a third minimum distance which is less than the second minimum distance, and an edge of the electrically insulating and thermally conductive layer has a fourth minimum distance from the at least one electrical via which is less than the third minimum distance.

29. The coil assembly according to claim 16, wherein the cooling arrangement includes at least one further cooling element, which is positioned on the winding of the at least one coil on a side of the at least one coil facing away from the circuit carrier.

30. The coil assembly according to claim 29, wherein the at least one further cooling element is thermally coupled to the winding of the at least one coil via at least one electrically insulating and thermally conductive structure.
